(19) United States
(12) Patent Application Publication
(10) Pub. No.: US 2026/0196289 A1
(43) Pub. Date: Jul. 9, 2026

(54) MEMORY DEVICE AND MEMORY MODULE

(71) Applicant: SAMSUNG ELECTRONICS CO., LTD., Suwon-si (KR)

(72) Inventors: Hochang JUNG, Suwon-si (KR); Chulwoo YI, Suwon-si (KR); Sunggeun DO, Suwon-si (KR); Sunghye CHO, Suwon-si (KR)

(73) Assignee: SAMSUNG ELECTRONICS CO., LTD., Suwon-si (KR)

(21) Appl. No.: 19/407,397

(22) Filed: Dec. 3, 2025

(30) Foreign Application Priority Data
Jan. 9, 2025 (KR) 10-2025-0003731

(51) Int. Cl. G11C 29/52; G06F 7/501; G11C 29/00

(52) U.S. Cl. CPC G11C 29/52; G06F 7/501; G11C 29/702

(57) ABSTRACT

A memory device may include: a memory cell array including a normal cell region storing data; and an error detector configured to detect an error of the data, the error detector may include: an error position information extractor configured to: in a first readout operation, extract first error position information of a first error bit in first data read from the normal cell region; and in a second readout operation, extract second error position information of a second error bit in the first data read from the normal cell region; and an error position comparator configured to: compare the first error position information with the second error position information; and output a signal based on a result of the comparison of the first error position information and the second error position information.

### CROSS-REFERENCE TO RELATED APPLICATION

This application is based on and claims priority under 35 U.S.C. § 119 to Korean Patent Application No. 10-2025-0003731, filed on Jan. 9, 2025, in the Korean Intellectual Property Office, the disclosure of which is incorporated by reference herein in its entirety.

### BACKGROUND

The present disclosure relates to a semiconductor device, and more particularly, to a volatile memory device and a memory module.

Memories used in servers essentially need an error extraction and correction function so as to maintain data integrity and guarantee reliability, availability, and scalability (RAS). An error correction code (ECC) operation may be performed at a memory module level, and on-die ECC technology for correcting an error by memory cell units in a memory chip.

Furthermore, an error incapable of being corrected through on-die ECC may occur. In this case, technology for repairing a cell defect occurring in a manufacturing process is used. Redundancy repair technology is used where a row or a column, including a memory cell where a defect occurs, is replaced by normal row or column units. Because defects of memory cells caused by scaling-down of a semiconductor memory device are rapidly increasing, there is a problem where a memory chip size increases due to redundancy security for replacing defect cells by using related art redundancy repair technology. Also, a row or column redundancy circuit is configured by units of a plurality of rows (four word lines or two word lines) or a plurality of columns (four bit lines or eight bit lines). That is, a number of resources are unnecessarily consumed for relieving a simple single 1-bit defect.

### SUMMARY

In a case where an error bit is a correctable error bit capable of being corrected by an error detector, and an addition value is greater than a threshold value, embodiments of the disclosure may change the addition value to an uncorrectable error bit to perform processing thereon.

Embodiments of the disclosure provide a memory device and a memory module, in which a defect cell may be extracted despite performing readout a plurality of times in a test process of the memory device, and a yield rate of memory devices may be enhanced.

According to an aspect of the disclosure, a memory device may include: a memory cell array including a normal cell region storing data; and an error detector configured to detect an error of the data, the error detector may include: an error position information extractor configured to: in a first readout operation, extract first error position information of a first error bit in first data read from the normal cell region; and in a second readout operation, extract second error position information of a second error bit in the first data read from the normal cell region; and an error position comparator configured to: compare the first error position information with the second error position information; and output a signal based on a result of the comparison of the first error position information and the second error position information.

According to an aspect of the disclosure, a memory device may include: a memory cell array including a normal cell region storing data; and an error detector configured to detect an error of the data, the error detector may include: an error position information extractor configured to: in a first readout operation, extract first error position information about a first error bit in first data read from the normal cell region; and in a second readout operation, extract second error position information about a second error bit in the first data read from the normal cell region; an error position comparator configured to: compare the first error position information with the second error position information; and output a signal based on a result of the comparison. The memory device may further include: an adder configured to perform an addition operation based on the signal; and a decision circuit configured to determine whether error bits including the first error bit and the second error bit are correctable, based on an addition value of the adder.

According to an aspect of the disclosure, a memory module may include: a printed circuit board; and a plurality of memory chips on the printed circuit board, each of the plurality of memory chips may include: a memory cell array configured to store data and a parity bit; and an error detector configured to detect an error of the data, based on the data and the parity bit, the error detector may include: an error position information extractor configured to extract nth error position information about an nth error bit in an nth data read from the memory cell array in an nth readout operation and extract an n+1th error position information about an n+1th error bit in an n+1th data read from the memory cell array in an n+1th readout operation, where n is a natural number. The error detector may further include: an error position comparator configured to: compare the nth error position information with the n+1th error position information; and output a signal based on a result of the comparison of the nth error position information and the n+1th error position information. The error detector may further include: an adder configured to perform an addition operation based on the signal; and a decision circuit configured to determine whether error bits including the nth error bit and the n+1th error bit are correctable, based on an addition value of the adder.

A method of operating a memory device, may include: in a first readout operation, extracting first error position information about a first error bit in first data read from a normal cell region of the memory device; in a second readout operation, extracting second error position information about a second error bit in the first data read from the normal cell region; comparing the first error position information with the second error position information; outputting a signal based on a comparison result; performing an addition operation based on the signal; and determining whether error bits comprising the first error bit and the second error bit are correctable, based on an addition value of the addition operation.

### BRIEF DESCRIPTION OF THE DRAWINGS

The above and/or other aspects will be more clearly understood from the following detailed description taken in conjunction with the accompanying drawings in which:

FIG. 1 is a block diagram illustrating a memory system according to one or more embodiments;

FIG. 2 is a block diagram illustrating a memory device according to one or more embodiments;

FIG. 3 is a block diagram illustrating some elements of a memory device according to one or more embodiments;

FIG. 4 is a flowchart illustrating a test method of a memory device, according to one or more embodiments;

FIG. 5 is a block diagram illustrating an operation of a memory device when performing a first readout operation, according to one or more embodiments;

FIG. 6 is a block diagram illustrating an operation of a memory device when performing a second readout operation, according to one or more embodiments;

FIG. 7 is a block diagram illustrating an operation of a memory device when performing a first readout operation, according to one or more embodiments;

FIG. 8 is a block diagram illustrating an operation of a memory device when performing a second readout operation, according to one or more embodiments;

FIG. 9 is a block diagram illustrating some elements of a memory device according to one or more embodiments;

FIG. 10 is a flowchart illustrating a test method of a memory device, according to one or more embodiments;

FIG. 11 is a flowchart illustrating a test method of a memory device, according to one or more embodiments;

FIG. 12 is a block diagram illustrating an operation of a memory device when performing a first readout operation, according to one or more embodiments;

FIG. 13 is a block diagram illustrating an operation of a memory device when performing a second readout operation, according to one or more embodiments;

FIG. 14 is a block diagram illustrating an operation of a memory device when performing a third readout operation, according to one or more embodiments;

FIG. 15 is a block diagram illustrating an operation of a memory device when performing a first readout operation, according to one or more embodiments;

FIG. 16 is a block diagram illustrating an operation of a memory device when performing a second readout operation, according to one or more embodiments;

FIG. 17 is a block diagram illustrating an operation of a memory device when performing a third readout operation, according to one or more embodiments;

FIG. 18 is a block diagram illustrating a storage system according to one or more embodiments;

FIG. 19 is a block diagram illustrating a computer system equipped with dynamic random access memory (DRAM) for performing an error correction code (ECC) operation, according to one or more embodiments; and

FIG. 20 is a block diagram illustrating an example where a memory device according to one or more embodiments is applied to a computing system.

### DETAILED DESCRIPTION

Hereinafter, embodiments will be described in detail with reference to the accompanying drawings.

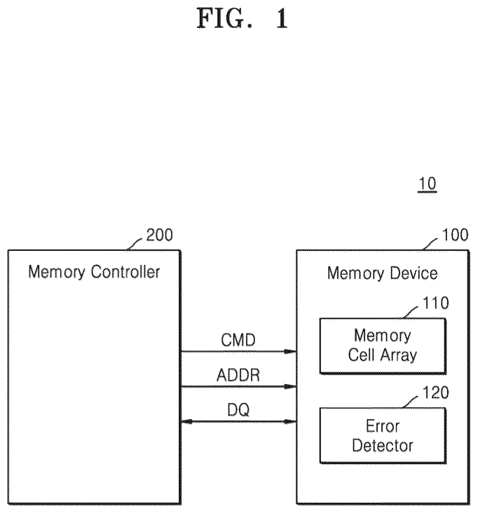

FIG. 1 is a block diagram illustrating a memory system 10 according to one or more embodiments.

Referring to FIG. 1, the memory system 10 may include a memory controller 200 and a memory device 100. The memory controller 200 may overall control an operation of the memory system 10 and may control overall data exchange between an external host and the memory device 100.

The memory controller 200 may control the memory device 100. For example, the memory controller 200 may apply various commands to the memory device 100 to control an operation of the memory device 100. For example, based on a request of a host, the memory controller 200 may control the memory device 100 to write data or read data. The memory controller 200 may transfer a command CMD and an address ADDR to the memory device 100 and may transfer or receive a data signal DQ to or from the memory device 100.

The memory device 100 may receive the command CMD and the address ADDR from the memory controller 200 and may transfer or receive the data signal DQ to or from the memory controller 200. The memory device 100 may include a memory cell array 110 and an error detector 120.

For example, the memory device 100 may be dynamic random access memory (DRAM) such as double data rate synchronous dynamic random access memory (DDR SDRAM), low power double data rate (LPDDR) SDRAM, graphics double data rate (GDDR) SDRAM, low power double data rate (LPDDR), or Rambus dynamic random access memory (RDRAM), or may be an arbitrary volatile memory device requiring an error correction operation.

The memory cell array 110 may include a plurality of memory cells, which are respectively connected to word lines and bit lines and are arranged in a row direction and a column direction. Each of the memory cells may be configured with a cell capacitor and an access transistor. A gate of the access transistor may be connected to one of the word lines arranged in the row direction. One end of the access transistor may be connected to a bit line or a complementary bit line arranged in the column direction. The other end of the access transistor may be connected to the cell capacitor.

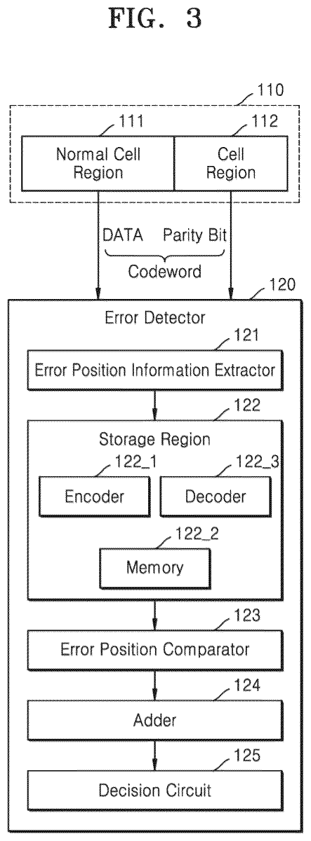

According to one or more embodiments, the error detector 120 may be implemented with software, firmware, and/or hardware. According to one or more embodiments, the number of a correctable error (CE) bit capable of being corrected by the error detector 120 may be 1. In a test process of the memory device 100, the error detector 120 may compare pieces of defect position information about a single bit error of data to perform an addition operation based on a comparison result. When the addition value is greater than a threshold value, which is a correctable error bit, the error detector 120 may change the addition value to an uncorrectable error bit to perform processing thereon. Therefore, in the test process of the memory device 100, the error detector 120 may perform readout a plurality of times to extract a defect cell, and thus, the yield rate of the memory device 100 may be enhanced. A case where the number of a CE bit capable of being corrected by the error detector 120 is 1 will be described below in detail with reference to FIGS. 3 to 8.

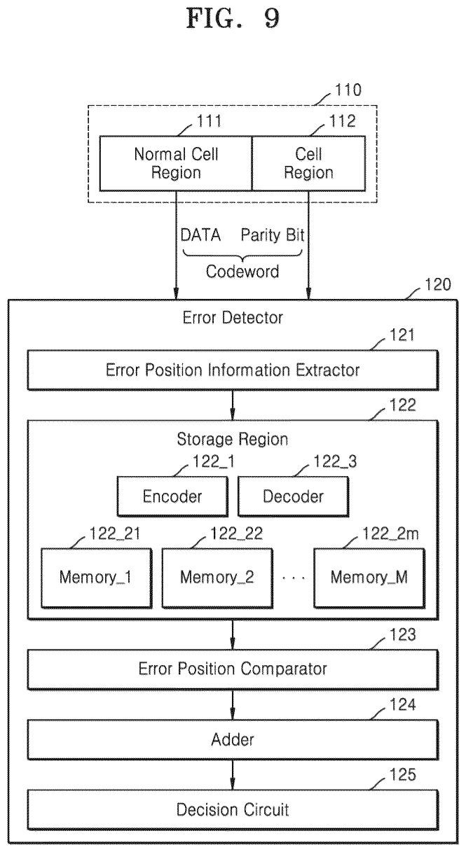

According to one or more embodiments, the number of a CE bit capable of being corrected by the error detector 120 may be a 2. In a test process of the memory device 100, the error detector 120 may compare pieces of defect position information about a multi-bit error of data to perform an addition operation based on a comparison result. When the addition value is greater than a threshold value, which is a correctable error bit, the error detector 120 may change the addition value to an uncorrectable error bit to perform processing thereon. Therefore, in the test process of the memory device 100, the error detector 120 may perform readout a plurality of times to extract a defective cell, and thus, the yield rate of the memory device 100 may be enhanced. A case where the number of a CE bit capable of being corrected by the error detector 120 is 2 will be described below in detail with reference to FIGS. 9 to 17.

In one or more embodiments, in the memory device 100, for example, as manufacturing process technology advances, the memory capacity of DRAM is increasing. As scaling down process technology advances, the number of faulty memory cells is increasing. To secure a yield rate, faulty memory cells may be replaced with redundant memory cells and may thus be repaired. It may be impossible to secure a sufficient yield rate based on redundant repair scheme. Therefore, a method of correcting error bits by applying an ECC algorithm to DRAM may be proposed.

The ECC algorithm may extract errors occurring in a process of writing and reading data and may provide an ECC function capable of correcting the errors. To provide data integrity, DRAM may use an ECC circuit. The ECC circuit may perform an ECC operation using parity bits in a process of extracting/correcting an error. Accordingly, DRAM may need to secure a separate memory region for storing parity bits.

The faulty memory cells may include defective cells and weak cells. The defective cells may denote cells which are defective in hardware, and the weak cells may denote cells which are defective in software. The weak cells may denote cells representing various device characteristic degradations. For example, the weak cells may include a cell having a short refresh time and a cell representing a cell write characteristic degradation or a variable retention time.

The error detector 120 may generate parity bits on only a faulty memory cell in the memory device 100 and may perform an ECC operation of extracting and correcting an error of a faulty memory cell by using the parity bits.

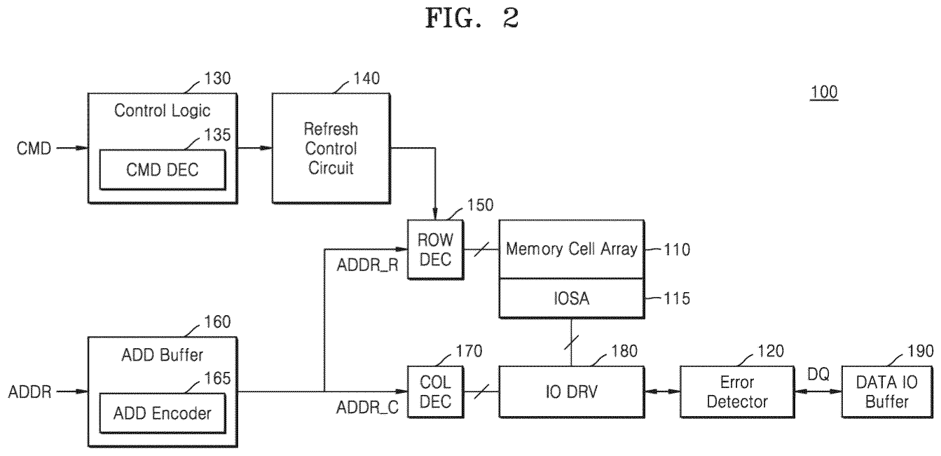

FIG. 2 is a block diagram illustrating a memory device 100 according to one or more embodiments.

Referring to FIG. 2, the memory device 100 may include a memory cell array 110 including a plurality of memory cells, an error detector 120, a control logic 130, a command decoder 135, a refresh control circuit 140, an address buffer 160, an address encoder 165, a row decoder 150, a column decoder 170, an input/output (IO) sense amplifier 115, an IO driver 180, and a data IO buffer 190.

The control logic 130 may control an operation of the memory device 100. For example, the control logic 130 may generate control signals to allow the memory device 100 to perform a write operation or a read operation. The control logic 130 may include a command decoder 135, which decodes a command CMD received from the memory controller 200.

The command decoder 135 may decode the command CMD input from the outside (for example, the memory controller 200 of FIG. 1) to generate one or more control signals for driving the memory device 100.

The refresh control circuit 140 may perform control to perform an auto refresh operation in response to a refresh command, or may perform control to perform a self-refresh operation in response to a self-refresh entry command.

The address buffer 160 may receive an address ADDR, including a row address ADD_R and a column address ADD_C, from a memory controller (200 of FIG. 1). The address buffer 160 may provide the received row address ADD_R to the row decoder 150 and may provide the received column address ADD_C to the column decoder 170. For example, the address buffer 160 may provide the row decoder 150 with the row address ADD_R for selecting a row and may provide the column decoder 170 with the column address ADD_C for selecting a column. The address buffer 160 may include an address encoder 165.

The address encoder 165 may encode the received row address ADD_R and the received column address ADD_C and may respectively provide an encoded row address ADD_R and an encoded column address ADD_C to the row decoder 150 and the column decoder 170.

ECC decoding may be performed on data DATA by the error detector 120, and then, the data DATA may be provided to the memory controller 200 through the data IO buffer 190. The data IO buffer 190 may provide the data DATA to the error detector 120 in a write operation, based on a clock signal provided from the memory controller 200. The data IO buffer 190 may provide the data DATA, provided from the error detector 120 to the memory controller 200 in a read operation.

In one or more embodiments, the error detector 120 may use various methods such as parity check, cyclical redundancy code (CRC) check, checksum check, and hamming code. The error detector 120 may perform an ECC operation on a faulty memory cell of the memory cell array 110 in response to an ECC control signal. The error detector 120 may adaptively perform an ECC operation in an X8 mode or an X4 mode of the memory device 100.

The error detector 120 may generate parity bits on data which is to be written in a partial region (for example, a normal cell region 111 of FIG. 3) of the memory cell array 110. The parity bits generated by the error detector 120 may be stored in the partial region (for example, a cell region 112 of FIG. 3) of the memory cell array 110. In some embodiments, the cell region 112 may correspond to an ECC cell region. Also, the normal cell region 111 may be referred to as a first cell region, and the cell region 112 may be referred to as a second cell region.

Data read from the normal cell region 111 and parity bits read from a parity region may be sensed and amplified by the IO sense amplifier 115. The error detector 120 may extract and correct an error bit included in the data read from the normal cell region 111 by using the parity bits.

FIG. 3 is a block diagram illustrating some elements of a memory device 100 according to one or more embodiments. The block diagram of FIG. 3 illustrates some elements of the memory cell array 110 and the error detector 120 of FIG. 2.

Referring to FIG. 3, the memory cell array 110 may include a normal cell region 111 and a cell region 112. In a test process, the error detector 120 may generate a parity bit corresponding to data DATA so as to extract and correct an error of the data DATA. The data DATA may be stored in the normal cell region 111, and the parity bit may be stored in the cell region 112.

In response to a test read command, the error detector 120 may read the data DATA stored in the normal cell region 111 and the parity bit stored in the cell region 112, from the memory cell array 110 by codeword units. Herein, an example where the data DATA consists of 128 bits and error position information described below consists of 7 bits may be described, but the disclosure is not limited thereto. For example, the data DATA may consist of a maximum of 4,096 bits, and the error position information may consist of a maximum of 512 bits.

In one or more embodiments, test bits may include the error position information. In some embodiments, the test bits may include the error position information and a check bit. Herein, the check bit may be defined as a bit representing whether the error position information indicates an error bit. As a detailed example, the 7-bit error position information corresponding to the 128-bit data DATA is implemented with a minimal number of bits to improve test operation efficiency. As result, while the 7-bit error position information may indicate which specific bit in the 128-bit data DATA is erroneous, it may not indicate that there is no error in the 128-bit data DATA. To complement this, the check bit may be configured to represent whether corresponding error position information indicates an error of a specific bit (or whether data corresponding to a check bit includes an error bit).

In one or more embodiments, the test bits may be 8 or more bits. For example, if there are 8 test bits, 7 bits of the 8 bits may be used as error position information, and 1 bit thereof may be the check bit representing whether the error position information indicates an error of a specific bit. For example, 7 bits corresponding to the error position information may consist of 0 or 1, and 1 bit corresponding the check bit may consist of 0 or 1.

For example, when a value of the check bit is 0, data corresponding to a the check bit may represent including an error, and when the value of the check bit is 1, data corresponding to the check bit may represent including no error.

The error detector 120 may include a error position information extractor 121, a storage region 122, an error position comparator 123, an adder 124, and a decision circuit 125.

In one or more embodiments, the adder 124 and the decision circuit 125 may be expressed as another element, and the adder 124 may include the decision circuit 125.

According to one or more embodiments, the number of a CE bit capable of being corrected by the error detector 120 may be 1. For example, the error detector 120 may extract first error position information about a first error bit of first data in a first readout operation of the memory device 100 and may extract second error position information about a second error bit of the first data in a second readout operation. The error detector 120 may compare the extracted first error position information with the extracted second error position information to output a signal based on a comparison result. For example, when the first error position information does not match the second error position information, the adder 124 may perform a +1 addition operation. When an addition value is greater than a threshold value (for example, the accumulated number of error positions is greater than 1), the adder 124 may change the each of first error bit and the second error bit to an uncorrectable error bit to perform processing thereon.

The error position information extractor 121 may extract error position information corresponding to an error bit included in the data DATA read from the normal cell region 111. For example, the error position information extractor 121 may extract the first error position information about the first error bit included in the first data read from the normal cell region 111 in the first readout operation and may extract the second error position information about the second error bit included in the first data read from the normal cell region 111 in the second readout operation.

The error position information extractor 121 may compare the read data with reference data stored in a table to extract an error bit and may generate error position information about the extracted error bit. For example, the error position information extractor 121 may compare the reference data with the first data read from the normal cell region 111 in the first readout operation and may thus extract the first error bit to detect the first error position information, and the error position information extractor 121 may compare the reference data with the first data read from the normal cell region 111 in the second readout operation and may thus extract the second error bit to detect the second error position information.

The storage region 122 may include an encoder 122_1, a decoder 122_3, and a memory 122_2. The storage region 122 may store error position information generated while testing the memory device 100.

The encoder 122_1 may perform an operation of detecting an error bit in data read from the memory cell array 110 and generating error position information indicating the detected error bit. For example, when data consists of 128 2⁷ bits, error position information for indicating an error bit among the 128 bits may consist of 7 bits. As a detailed example, the encoder 122_1 may detect an error bit in data read based on a test bit corresponding to the data read from the memory cell array 110.

The encoder 122_1 may generate a test bit associated with data. For example, the encoder 122_1 may encode the first data to extract the first error position information and may encode the second data to extract the second error position information. The first error position information may be included in a test bit corresponding to the first error bit, and the second error position information may be included in a test bit corresponding to the second error bit. Here, a test bit may include error position information of 7 bits and may further include a check bit of 1 bit. The encoder 122_1 may transfer the first error position information and the second error position information to the memory 122_2. The memory 122_2 may store the first error position information and the second error position information. When the number of a CE bit capable of being corrected by the error detector 120 is 1, the memory 122_2 may be provided as one. The memory 122_2 may store error position information which generated while testing the memory device 100. For example, the memory 122_2 may be implemented as a memory device such as an anti-fuse array, a content addressable memory (CAM), a register, or static random access memory (SRAM). For example, in FIG. 3, the memory 122_2 is illustrated in the memory device 100, but one or more embodiments is not limited thereto and the memory 122_2 may be provided as a separate element outside the memory device 100. In some embodiments, the encoder 122_1 may perform ECC encoding.

The decoder 122_3 may decode error position information. In some embodiments, an operation of the decoder 122_3 may be replaced with an operation of an ECC decoder performing ECC decoding, and a configuration of the decoder 122_3 may be omitted. In this case, because the configuration of the decoder 122_3 is omitted, a design area of the memory device 100 may be reduced.

The error position comparator 123 may compare the first error position information with the second error position information to output a signal based on a comparison result. The error position comparator 123 may receive the first error position information stored in the memory 122_2 and/or the second error position information stored in the memory 122_2 to perform a comparison thereof and may output a signal based on a comparison result. For example, when the first error position information matches the second error position information as the comparison result, the error position comparator 123 may output a match signal P. For example, when the first error position information does not match the second error position information as the comparison result, the error position comparator 123 may output a mismatch signal F.

For example, the error position comparator 123 may compare the first error position information indicating the first error bit with the second error position information indicating the second error bit. That is, the error position comparator 123 may compare the first error position information of 7 bits with the second error position information of 7 bits. However, one or more embodiments is not limited thereto. When the first error position information matches the second error position information, the error position comparator 123 may output the match signal P, and when the first error position information does not match the second error position information, the error position comparator 123 may output the mismatch signal F.

For example, the error position comparator 123 may preferentially check a first check bit corresponding to the first error position information and a second check bit corresponding to the second error position information. The error position comparator 123 may skip an operation of comparing the first error position information with the second error position information based on that each of the first error position information and the second error position information does not indicate an error of a certain bit in the first check bit and the second check bit (i.e., indicating that there is no error in each of data corresponding to the first check bit and data corresponding to the second check bit). The error position comparator 123 may start the operation of comparing the first error position information with the second error position information based on that each of the first error position information and the second error position information indicates an error of a certain bit in the first check bit and the second check bit (i.e., indicating that there is an error in each of the data corresponding to the first check bit and the data corresponding to the second check bit). In other words, the first check bit may indicate presence of a first error bit, and the second check bit may indicate presence of a second error bit.

In one or more embodiments, when it is assumed that the number of a CE bit is 1, an operation of the error position comparator 123 may be performed. On the other hand, when the number of the CE bit is 2, an operation of the error position comparator 123 will be described below in detail with reference to FIG. 9.

The adder 124 may receive a signal of the error position comparator 123 to perform an addition operation. For example, in a case where the error position comparator 123 outputs the match signal P, the adder 124 may not perform an addition operation. For example, in a case where the error position comparator 123 outputs the mismatch signal F, the adder 124 may perform an addition operation.

The decision circuit 125 may determine or decide whether an error bit in data is a CE bit or an uncorrectable error bit based on an addition value of the adder 124.

In one or more embodiments, in a case where the number of a CE bit capable of being corrected by the error detector 120 is 1, when first error position information about a first error bit included in first data in a first readout operation does not match second error position information about a second error bit included in the first data in a second readout operation, the adder 124 may perform an addition operation, and when the accumulated number of error positions as a result of the addition operation is greater than 1, the decision circuit 125 may change the error bit in data to an uncorrectable error bit.

In one or more embodiments, in a case where the number of a CE bit is 1, when nth error position information about an error bit included in data in an nth readout operation includes a single bit error, and n+1th error position information about an error bit included in data in an n+1th readout operation includes a single bit error, the error detector 120 may compare whether the nth error position information matches the n+1th error position information, and when a mismatch therebetween is determined, the error detector 120 may change the error bits included in data in the nth readout operation and the n+1th readout operation to an uncorrectable error (UE) bit through an addition operation. Accordingly, in a test process of the memory device 100, readout may be performed a plurality of times, and thus, faulty cells may be extracted.

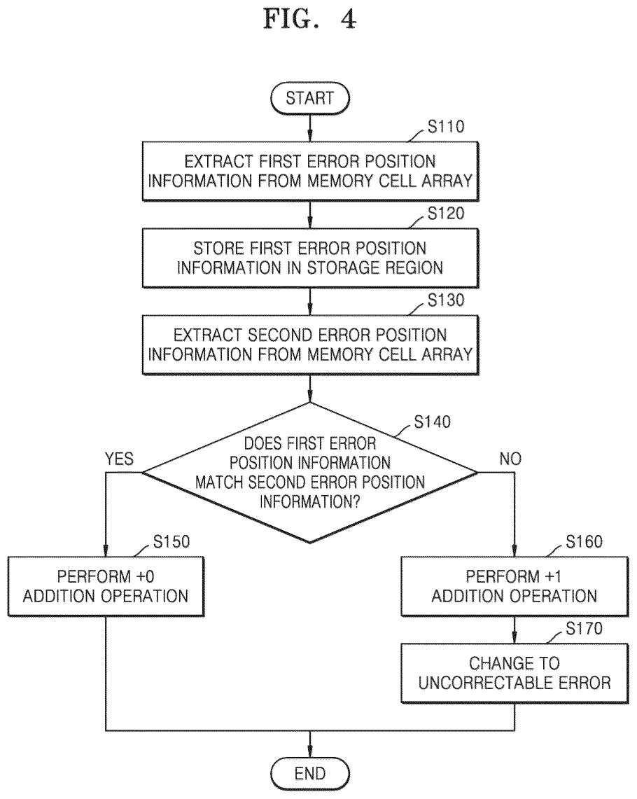

FIG. 4 is a flowchart illustrating a test method of a memory device, according to one or more embodiments.

Referring to FIG. 4, in operation S110, the error position information extractor 121 may extract first error position information about a first error bit included in first data read from the memory cell array 110. For example, the error position information extractor 121 may extract the first error position information about the first error bit included in the first data read from the normal cell region 111 in a first readout operation. The first error bit may be assumed to include a single bit error. In one or more embodiments, the error position information extractor 121 may perform the first readout operation on the memory cell array 110 to extract pieces of first error position information corresponding to pieces of first data including an error bit of n (where n may be 1) or less.

In operation S120, the first error position information may be stored in the storage region 122. For example, an encoder may encode the first data received thereby to extract the first error position information, and a memory may store the first error position information.

In operation S130, the error position information extractor 121 may extract second error position information about a second error bit included in the first data read from the memory cell array 110. For example, the error position information extractor 121 may extract the second error position information about the second error bit included in the first data read from the normal cell region 111 in a second readout operation. The second error bit may include a single bit error. In one or more embodiments, the error position information extractor 121 may perform the second readout operation on the memory cell array 110 to extract pieces of second error position information corresponding to pieces of second data including an error bit of n or less.

In operation S140, the error position comparator 123 may compare whether the first error position information matches the second error position information. For example, the error position comparator 123 may compare whether the first error position information matches the second error position information. The error position comparator 123 may output a signal based on a comparison result. For example, when the first error position information matches the second error position information, the error position comparator 123 may output a match signal. For example, when the first error position information does not match the second error position information, the error position comparator 123 may output a mismatch signal.

When the first error position information matches the second error position information, namely, when the error position comparator 123 outputs the match signal, operation S150 may be performed. For example, when the match signal is provided from the error position comparator 123, the adder 124 may not perform an addition operation. Here, the addition operation not being performed may denote that a +0 addition operation is performed.

When the first error position information does not match the second error position information, namely, when the error position comparator 123 outputs the mismatch signal, operation S160 may be performed. For example, when the mismatch signal is provided from the error position comparator 123, the adder 124 may perform an addition operation. The addition operation being performed may denote that a +1 addition operation is performed.

In one or more embodiments, the adder 124 may add the number of pieces of first uncorrectable error position information based on a result of comparison of pieces of first error position information and pieces of second error position information. Also, in one or more embodiments, the adder 124 or the decision circuit 125 may determine whether a memory device has error based on an addition result.

In one or more embodiments, an operation of adding the number of pieces of first uncorrectable error position information by using the adder 124 or the decision circuit 125 may include an operation of removing pieces of error position information overlapping between the pieces of first error position information and the pieces of second error position information. Also, the adder 124 may include an operation of summating the pieces of first error position information and the pieces of second error position information to extract pieces of first uncorrectable error position information, based on a removal result.

In operation S170, when an addition value is greater than a threshold value, which is a correctable error, the decision circuit 125 may change the addition value to an uncorrectable error. For example, when the number of a correctable error of the decision circuit 125 is 1, the threshold value may be 1, and thus, when the addition value is 2, the decision circuit 125 may change the addition value to an uncorrectable error. The decision circuit 125 may read out pieces of data a plurality of times to repeat a comparison operation between pieces of error position information, and thus, may accumulate the number of times an uncorrectable error is determined. The decision circuit 125 may determine a test pass or a test fail on the memory device, based on the final accumulated number of times an uncorrectable error is determined.

In an operating method of the memory device according to one or more embodiments, in a case where a CE bit is determined, when first error position information about a first error bit included in first data in a first readout operation does not match second error position information about a second error bit included in the first data in a second readout operation, an addition operation may be performed, and when the addition value is greater than a threshold value, which is a CE bit, the operating method may change each of first error bit and the second error bit to an uncorrectable error bit.

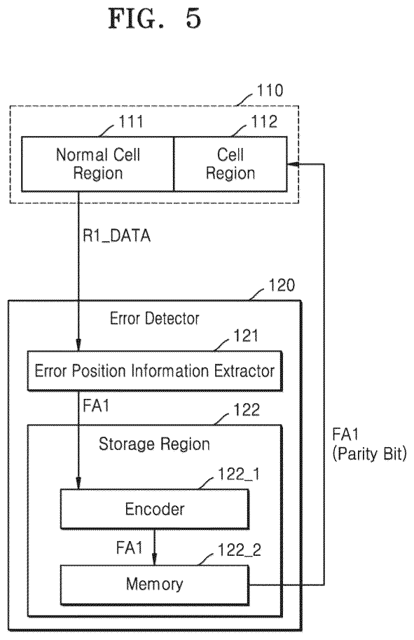

FIG. 5 is a block diagram illustrating an operation of a memory device when performing a first readout operation, according to one or more embodiments. In the following description, description that is substantially the same as the description of FIG. 3 is omitted.

Referring to FIG. 5, in a first readout operation, first data may be read from a normal cell region 111 of a memory cell array 110. Read first data R1_DATA may be provided to an error position information extractor 121.

The error position information extractor 121 may extract first error position information FA1 about a first error bit included in the read first data R1_DATA. For example, the error position information extractor 121 may compare the read first data R1_DATA with reference data stored therein to extract the first error position information FA1. The error position information extractor 121 may provide the first error position information FA1 to a storage region 122.

The storage region 122 may receive the first error position information FA1. For example, an encoder 122_1 may encode the read first data R1_DATA to extract or receive the first error position information FA1. A memory 122_2 may store the first error position information FA1.

The storage region 122 may store the first error position information FA1. For example, the memory 122_2 may store the first error position information FA1. For example, the first error position information FA1 may be stored as 7 bits among parity bits, which are 8 bits.

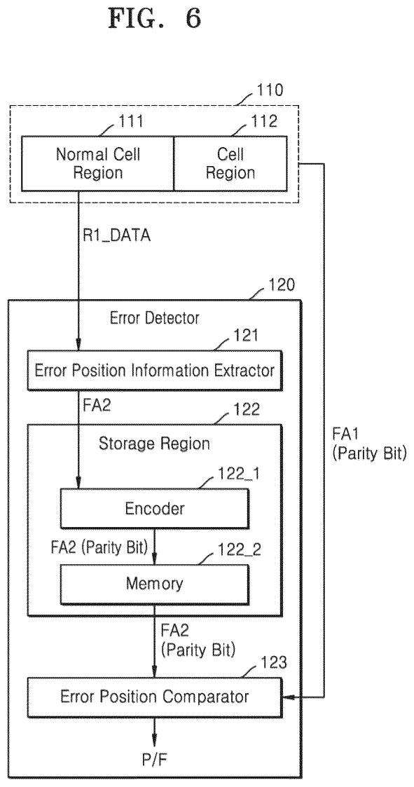

FIG. 6 is a block diagram illustrating an operation of a memory device when performing a second readout operation, according to one or more embodiments.

Referring to FIG. 6, in a second readout operation, first data may be read from a normal cell region 111 of a memory cell array 110. Read first data R1_DATA may be provided to an error position information extractor 121.

The error position information extractor 121 may extract second error position information FA2 about a second error bit included in the read first data R1_DATA. For example, the error position information extractor 121 may compare the read first data R1_DATA with reference data stored therein to extract the second error position information FA2. The error position information extractor 121 may provide the second error position information FA2 to a storage region 122.

The storage region 122 may receive the second error position information FA2. For example, an encoder 122_1 may encode the read first data R1_DATA to extract or receive the second error position information FA2. A memory 122_2 may store the second error position information FA2. For example, the second error position information FA2 may be stored as 7 bits among test bits, which are 8 bits.

An error position comparator 123 may compare the second error position information FA2, provided from the memory 122_2, with first error position information FA1 stored in a cell region 112. The error position comparator 123 may compare the first error position information FA1 with the second error position information FA2 to output a signal P/F based on a comparison result. For example, when the first error position information FA1 matches the second error position information FA2, the error position comparator 123 may output a match signal P. For example, when the first error position information FA1 does not match the second error position information FA2, the error position comparator 123 may output a mismatch signal F.

In one or more embodiments, in a case where the number of a CE bit is 1, the error detector 120 may compare whether nth error position information about an nth error bit included in data in an nth readout operation matches n+1th error position information about an n+1th error bit included in the data in an n+1th readout operation, and when a mismatch therebetween is determined, an addition operation may be performed, and moreover, when an addition value is greater than 1, the error detector 120 may change each of the nth error bit and the n+1th error bit to an uncorrectable error bit to perform processing thereon. Accordingly, in a test process of the memory device, readout may be performed a plurality of times, and thus, faulty cells may be extracted.

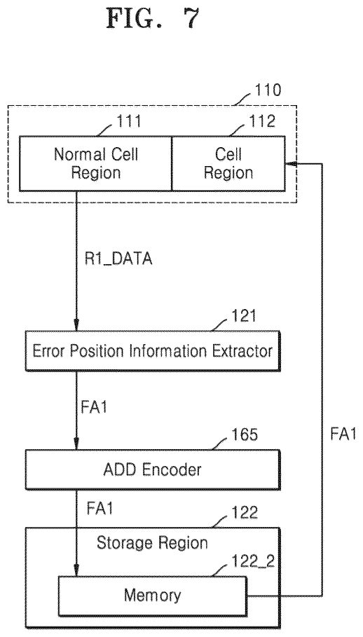

FIG. 7 is a block diagram illustrating an operation of a memory device when performing a first readout operation, according to one or more embodiments. In the following description, description that is substantially the same as the description of FIG. 5 is omitted.

Referring to FIG. 7, unlike FIG. 5, the memory device may be configured with an address encoder 165 instead of the encoder 122_1. The address encoder 165 of FIG. 7 may correspond to the address encoder 165 illustrated in FIG. 2.

In a first readout operation, first data may be read from a normal cell region 111 of a memory cell array 110. Read first data R1_DATA may be provided to an error position information extractor 121 (error position information detector).

The error position information extractor 121 may extract first error position information FA1 about a first error bit included in the read first data R1_DATA. For example, the error position information extractor 121 may compare the read first data R1_DATA with reference data stored therein to extract the first error position information FA1. The error position information extractor 121 may provide the first error position information FA1 to a storage region 122.

The address encoder 165 may receive the first error position information FA1. The address encoder 165 may extract the first error position information FA1. A memory 122_2 may store the first error position information FA1.

The storage region 122 may store the first error position information FA1. For example, the memory 122_2 may store the first error position information FA1. The first error position information FA1 may be stored as 7 bits among test bits, which are 8 bits.

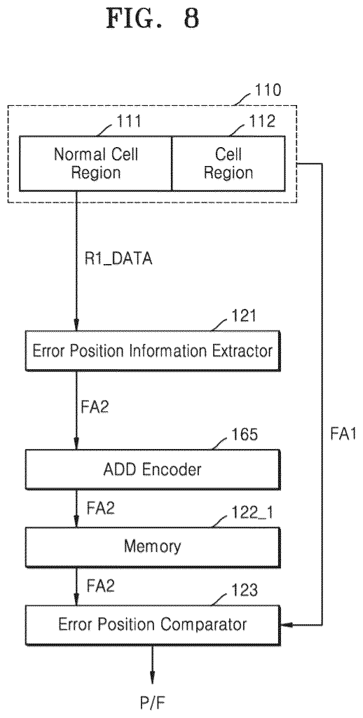

FIG. 8 is a block diagram illustrating an operation of a memory device when performing a second readout operation, according to one or more embodiments. In the following description, description that is substantially the same as the description of FIG. 6 is omitted.

Referring to FIG. 8, unlike FIG. 6, the memory device may be configured with an address encoder 165 instead of the encoder 122_1. The address encoder 165 of FIG. 8 may correspond to the address encoder 165 illustrated in FIG. 2.

In a second readout operation, first data may be read from a normal cell region 111 of a memory cell array 110. Read first data R1_DATA may be provided to an error position information extractor 121.

The error position information extractor 121 may extract second error position information FA2 about a second error bit included in the read first data R1_DATA. For example, the error position information extractor 121 may compare the read first data R1_DATA with reference data stored therein to extract the second error position information FA2. The error position information extractor 121 may provide the second error position information FA2 to a storage region 122.

The address encoder 165 may receive the second error position information FA2. The address encoder 165 may extract the second error position information FA2. A memory 122_2 may store the second error position information FA2. The second error position information FA2 may be stored as 7 bits among test bits, which are 8 bits.

An error position comparator 123 may compare the second error position information FA2, provided from the memory 122_2, with first error position information FA1 stored in a storage region 122. The error position comparator 123 may compare the first error position information FA1 with the second error position information FA2 to output a signal P/F based on a comparison result. For example, when the first error position information FA1 matches the second error position information FA2, the error position comparator 123 may output a match signal P. For example, when the first error position information FA1 does not match the second error position information FA2, the error position comparator 123 may output a mismatch signal F.

Referring to FIGS. 3 and 8, when the adder 124 receives the match signal P, the adder 124 may not perform an addition operation, and when the adder 124 receives the mismatch signal F, the adder 124 may perform the addition operation. For example, when the adder 124 receives the mismatch signal F, the adder 124 may perform a +1 addition operation. For example, in a case where the number of a correctable error bit of the adder 124 is 1, when the adder 124 receives the mismatch signal F to perform the +1 addition operation, the number of accumulated error positions as an addition value of the adder 124 may be 2 and may be greater than 1, and thus, the adder 124 may change the first error bit or the second error bit from the correctable error bit to an uncorrectable error bit.

In one or more embodiments, in a case where the number of a CE bit is 1, the error detector 120 may compare whether nth error position information about an nth error bit included in data in an nth readout operation matches n+1th error position information about an n+1th error bit included in the data in an n+1th readout operation, and when a mismatch therebetween is determined, an addition operation may be performed, and moreover, when an addition value is greater than 1, the error detector 120 may change the nth error bit or the n+1th error bit to an uncorrectable error bit. Accordingly, in a test process of the memory device, readout may be performed a plurality of times, and thus, faulty cells may be extracted.

FIG. 9 is a block diagram illustrating some elements of a memory device 100 according to one or more embodiments, The block diagram of FIG. 9 illustrates some elements of the memory cell array 110 and the error detector 120 of FIG. 2. In the following description, description that is substantially the same as the description of FIG. 3 is omitted.

Referring to FIG. 9, the number of a CE bit capable of being corrected by an error detector 120 according to one or more embodiments may be 2. For example, the error detector 120 may extract first error position information about a first error bit of first data in a first readout operation of the memory device 100 and may extract second error position information about a second error bit of the first data in a second readout operation. The error detector 120 may compare the extracted first error position information with the extracted second error position information to output a signal based on a comparison result. For example, when the first error position information does not match the second error position information, an adder 124 may perform a +1 addition operation. When it is determined by a decision circuit 125 that an addition value is greater than a threshold value, the adder 124 may change the addition value to an uncorrectable error bit to perform processing thereon.

An error position information extractor 121 may extract error position information corresponding to an error bit included in data DATA read from a normal cell region 111. For example, the error position information extractor 121 may extract third error position information about a third error bit included in first data read from the normal cell region 111 in a third readout operation.

The error position information extractor 121 may compare the read data with reference data stored in a table to extract an error bit and may generate error position information about the extracted error bit. For example, the error position information extractor 121 may compare reference data with the first data read from the normal cell region 111 to extract the third error bit and may thus generate the third error position information, in a third readout operation.

The storage region 122 may include an encoder 122_1, a decoder 122_3, a first memory 122_21, a second memory 122_22, and an mth memory 122_2m (where m may be a natural number of 3 or more). The storage region 122 may store error position information generated while testing the memory device 100.

According to one or more embodiments, when the number of a CE bit capable of being corrected by the error detector 120 is 2, the storage region 122 may include m number of memories. For example, when the number of the CE bit capable of being corrected by the error detector 120 is 2, the storage region 122 may include two memories (for example, the first memory 122_21 and the second memory 122_22). For example, when the number of the CE bit capable of being corrected by the error detector 120 is 3, the storage region 122 may include three memories (for example, the first memory 122_21, the second memory 122_22, and a third memory 122_23).

The encoder 122_1 may encode data. Here, an operation of encoding data may denote an operation of compressing data to extract first error position information about the data and second error position information about the data. The encoder 122_1 may generate a test bit associated with data. For example, the encoder 122_1 may extract or receive the third error position information and may extract or receive a test bit of the third error bit. The encoder 122_1 may transfer the third error position information to the memory 122_23.

The first memory 122_21 may store the first error position information, the second memory 122_22 may store the second error position information, and the third memory 122_23 may store the third error position information. The first memory 122_21, the second memory 122_22, and the mth memory 122_2m may store error position information generated while testing the memory device 100.

The decoder 122_3 may decode error position information. In some embodiments, an operation of the decoder 122_3 may be replaced with an operation of an ECC decoder performing ECC decoding, and a configuration of the decoder 122_3 may be omitted. In this case, because the configuration of the decoder 122_3 is omitted, a design area of the memory device 100 may be reduced.

The error position comparator 123 may compare the first error position information, the second error position information, and the third error position information to output a signal based on a comparison result. The error position comparator 123 may receive and compare the first error position information, the second error position information, and/or the third error position information to output a signal based on a comparison result.

For example, when the first error position information matches the third error position information as the comparison result, the error position comparator 123 may output a match signal P. For example, when the first error position information does not match the second error position information as the comparison result, the error position comparator 123 may output a mismatch signal F.

For example, when the second error position information matches the third error position information as the comparison result, the error position comparator 123 may output the match signal P. For example, when the second error position information does not match the second error position information as the comparison result, the error position comparator 123 may output the mismatch signal F.

For example, the error position comparator 123 may compare the second error position information included in the second error bit with the third error position information included in the third error bit. The error position comparator 123 may compare the second error position information of 7 bits with the third error position information of 7 bits. When the second error position information matches the third error position information, the error position comparator 123 may output the match signal P, and when the second error position information does not match the third error position information, the error position comparator 123 may output the mismatch signal F.

For example, the error position comparator 123 may compare the first error position information included in the first error bit with the third error position information included in the third error bit. The error position comparator 123 may compare the first error position information of 7 bits with the third error position information of 7 bits. When the first error position information matches the third error position information, the error position comparator 123 may output the match signal P, and when the first error position information does not match the third error position information, the error position comparator 123 may output the mismatch signal F.

For example, when the first error position information matches the third error position information, the error position comparator 123 may skip an operation of comparing the second error position information with the third error position information.

For example, the error position comparator 123 may compare a second CE bit included in the second error bit with a third CE bit included in the third error bit. That is, the error position comparator 123 may compare the second CE bit of 1 bit with the third CE bit of 1 bit. When the second CE bit matches the third CE bit, the error position comparator 123 may output the match signal P, and when the second CE bit does not match the third CE bit, the error position comparator 123 may output the mismatch signal F.

For example, the error position comparator 123 may compare a first CE bit included in the first error bit with the third CE bit included in the third error bit. That is, the error position comparator 123 may compare the first CE bit of 1 bit with the third CE bit of 1 bit. When the first CE bit matches the third CE bit, the error position comparator 123 may output the match signal P, and when the first CE bit does not match the third CE bit, the error position comparator 123 may output the mismatch signal F.

For example, when the first CE bit matches the third CE bit, the error position comparator 123 may skip an operation of comparing the second CE bit with the third CE bit.

In one or more embodiments, when it is assumed that the number of a CE bit is 2, an operation of the error position comparator 123 may be performed.

The adder 124 may receive a signal of the error position comparator 123 to perform an addition operation. For example, in a case where the error position comparator 123 outputs the match signal P, the adder 124 may not perform an addition operation. For example, in a case where the error position comparator 123 outputs the mismatch signal F, the adder 124 may perform an addition operation.

In one or more embodiments, in a case where the number of a CE bit 2, when first error position information about a first error bit included in first data in a first readout operation does not match second error position information about a second error bit included in the first data in a second readout operation, the adder 124 may perform an addition operation, and when the number of accumulated error positions as a result of the addition operation is greater than 2, the decision circuit 125 may change the error bits to uncorrectable error bits.

In one or more embodiments, in a case where the number of a CE bit is 3, when the first error position information about the first error bit included in the first data in the first readout operation, the second error position information about the second error bit included in the first data in the second readout operation, and third error position information about the third error bit included in the first data in the third readout operation do not match therebetween, the adder 124 may perform an addition operation, and when the number of accumulated error positions as a result of the addition operation is greater than 3, the decision circuit 125 may change the error bits to uncorrectable error bits.

In one or more embodiments, in a case where the number of a CE bit is 2, when first error position information about a first error bit included in first data in a first readout operation does not match second error position information about a second error bit included in the first data in a second readout operation, the adder 124 may perform an addition operation, and when the number of error bits is greater than a threshold value as a result of the addition operation, the decision circuit 125 may change the error bits to uncorrectable error bits.

In one or more embodiments, in a case where the number of a CE bit is 2, when nth error position information about an error bit included in data in an nth readout operation includes a single bit error, and n+1th error position information about an error bit included in data in an n+1th readout operation includes a single bit error, the error detector 120 may compare whether the nth error position information matches the n+1th error position information, and when a mismatch therebetween is determined, the error detector 120 may change the error bit to a UE bit based on an addition operation. Accordingly, in a test process of the memory device 100, readout may be performed a plurality of times, and thus, faulty cells may be extracted.

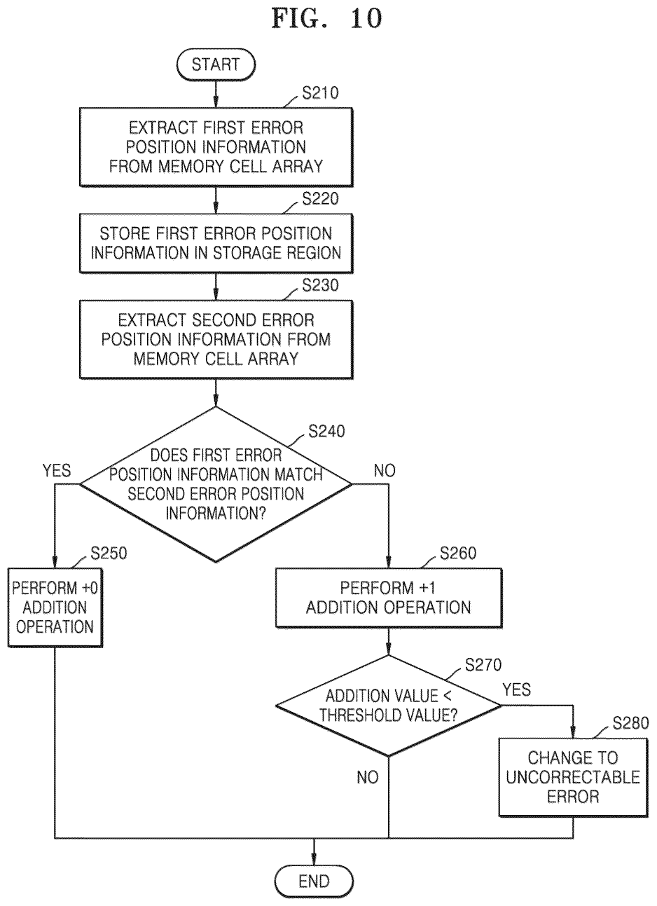

FIG. 10 is a flowchart illustrating a test method of a memory device, according to one or more embodiments.

Referring to FIG. 10, in operation S210, the error position information extractor 121 may extract first error position information about a first error bit included in first data read from the memory cell array 110. For example, the error position information extractor 121 may extract the first error position information about the first error bit included in the first data read from the normal cell region 111 in a first readout operation. The first error bit may be assumed to include a multi-bit error (for example, 2-bit error). In one or more embodiments, the error position information extractor 121 may perform the first readout operation on the memory cell array 110 to extract pieces of first error position information corresponding to pieces of first data including an error bit of n (where n may be a natural number of 2 or more) or less.

In operation S220, the first error position information may be stored in the storage region 122. For example, an encoder 122_1 may encode read first data to extract or receive the first error position information, and the first memory 122_21 may store the first error position information.

In operation S230, the error position information extractor 121 may extract second error position information about a second error bit included in the first data read from the memory cell array 110. For example, the error position information extractor 121 may extract the second error position information about the second error bit included in the first data read from the normal cell region 111 in a second readout operation. The second error bit may include a multi-bit error. In one or more embodiments, the error position information extractor 121 may perform the second readout operation on the memory cell array 110 to extract pieces of second error position information corresponding to pieces of second data including an error bit of n or less.

In operation S240, the error position comparator 123 may compare whether the first error position information matches the second error position information. For example, the error position comparator 123 may compare whether the first error position information matches the second error position information. The error position comparator 123 may output a signal based on a comparison result. For example, when the first error position information matches the second error position information, the error position comparator 123 may output a match signal. For example, when the first error position information does not match the second error position information, the error position comparator 123 may output a mismatch signal.

When the first error position information matches the second error position information, namely, when the error position comparator 123 outputs the match signal, operation S250 may be performed. For example, when the match signal is provided from the error position comparator 123, the adder 124 may not perform an addition operation. Here, the addition operation not being performed may denote that a +0 addition operation is performed.

When the first error position information does not match the second error position information, namely, when the error position comparator 123 outputs the mismatch signal, operation S260 may be performed. For example, when the mismatch signal is provided from the error position comparator 123, the adder 124 may perform an addition operation. The addition operation being performed may denote that a +1 addition operation is performed.

In one or more embodiments, the adder 124 may add the number of pieces of first uncorrectable error position information based on a result of comparison of pieces of first error position information and pieces of second error position information. Also, in one or more embodiments, the adder 124 or the decision circuit 125 may determine whether a memory device is faulty based on an addition result.

In one or more embodiments, an operation of adding the number of pieces of first uncorrectable error position information by using the adder 124 may include an operation of removing pieces of error position information overlapping between the pieces of first error position information and the pieces of second error position information. Also, the adder 124 may include an operation of summating the pieces of first error position information and the pieces of second error position information to extract pieces of first uncorrectable error position information, based on a removal result.

In operation S270, the decision circuit 125 may determine whether an addition value is less than a threshold value, which is a correctable error. For example, when the addition value of the adder 124 is +2, and the threshold value is +3, a test operation of the memory device may end. For example, when the addition value of the adder 124 is +3, and the threshold value is +2, operation S280 may be performed. In operation S280, the test operation of the memory device may end by changing to a correctable error.

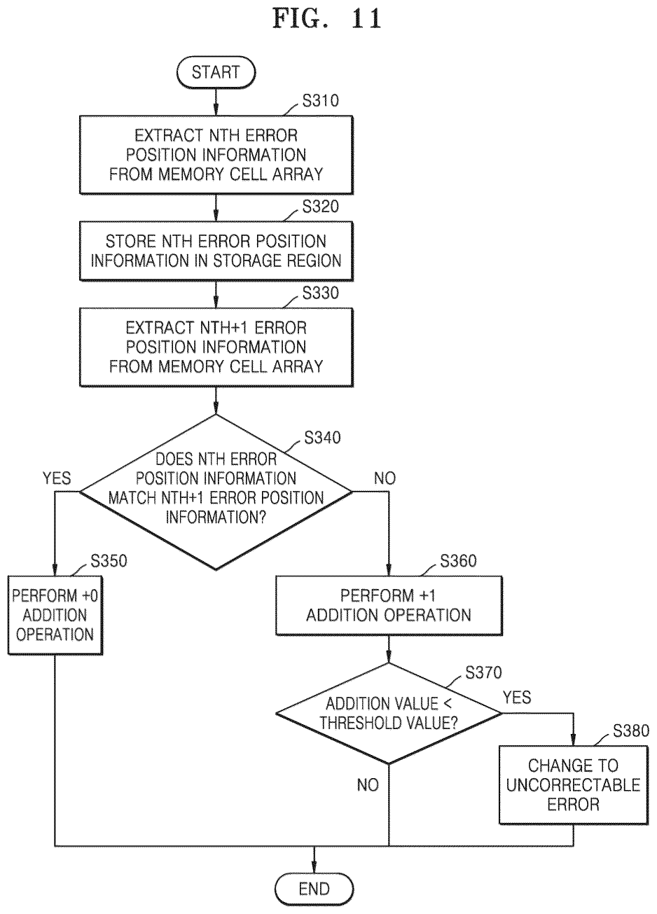

FIG. 11 is a flowchart illustrating a test method of a memory device, according to one or more embodiments.

Referring to FIG. 11, in operation S310, the error position information extractor 121 may extract nth error position information about an nth error bit included in data read from the memory cell array 110. For example, the error position information extractor 121 may extract the nth error position information about the nth error bit included in the data read from the normal cell region 111 in a first readout operation. The nth error bit may be assumed to include a multi-bit error (for example, 2 or more error bits). In one or more embodiments, the error position information extractor 121 may perform the first readout operation on the memory cell array 110 to extract pieces of first error position information corresponding to pieces of first data including an error bit of n (where n may be a natural number of 2 or more) or less.

In operation S320, the nth error position information may be stored in the storage region 122. For example, the encoder 122_1 may encode read data to extract or receive the nth error position information, and the mth memory 122_2m may store the nth error position information.

In operation S330, the error position information extractor 121 may extract n+1th error position information about an n+1th error bit included in the data read from the memory cell array 110. For example, the error position information extractor 121 may extract the n+1th error position information about the n+1th error bit included in the data read from the normal cell region 111 in a second readout operation. The n+1th error bit may include a multi-bit error. In one or more embodiments, the error position information extractor 121 may perform the second readout operation on the memory cell array 110 to extract pieces of second error position information corresponding to pieces of second data including an error bit of n or less.

In operation S340, the error position comparator 123 may compare whether the nth error position information matches the n+1th error position information. For example, the error position comparator 123 may compare whether the nth error position information matches the n+1th error position information. The error position comparator 123 may output a signal based on a comparison result. For example, when the nth error position information matches the n+1th error position information, the error position comparator 123 may output a match signal. For example, when the nth error position information does not match the n+1th error position information, the error position comparator 123 may output a mismatch signal.

When the nth error position information matches the n+1th error position information, namely, when the error position comparator 123 outputs the match signal, operation S350 may be performed. For example, when the match signal is provided from the error position comparator 123, the adder 124 may not perform an addition operation. Here, the addition operation not being performed may denote that a +0 addition operation is performed.

When the nth error position information does not match the n+1th error position information, namely, when the error position comparator 123 outputs the mismatch signal, operation S360 may be performed. For example, when the mismatch signal is provided from the error position comparator 123, the adder 124 may perform an addition operation. The addition operation being performed may denote that a +1 addition operation is performed.

In one or more embodiments, the decision circuit 125 may add the number of pieces of first uncorrectable error position information based on a result of comparison of pieces of first error position information and pieces of second error position information. Also, in one or more embodiments, the adder 124 may determine whether a memory device is faulty based on an addition result.

In one or more embodiments, an operation of adding the number of pieces of first uncorrectable error position information by using the adder 124 may further include an operation of obtaining the number of pieces of second uncorrectable error position information corresponding to pieces of third data including an error bit of more than n extracted through the first readout operation and an operation of adding the number of pieces of first uncorrectable error position information to the number of pieces of second uncorrectable error position information.

In operation S370, the decision circuit 125 may determine whether an addition value is less than a threshold value, which is a correctable error. For example, when the addition value of the adder 124 is +2, and the threshold value is +3, a test operation of the memory device may end. For example, when the addition value of the adder 124 is +3, and the threshold value is +2, operation S380 may be performed. In operation S380, the test operation of the memory device may end by changing to an uncorrectable error.

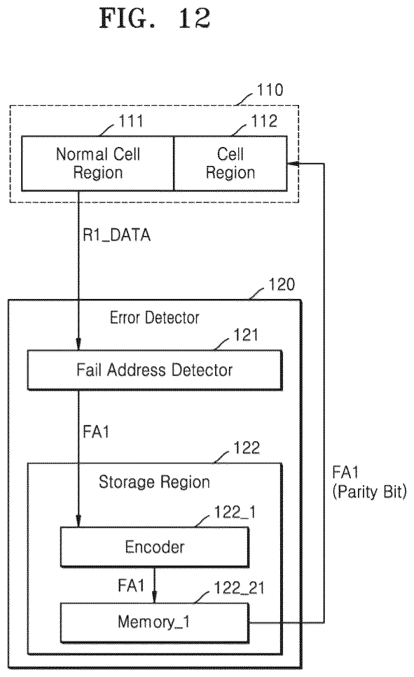

FIG. 12 is a block diagram illustrating an operation of a memory device when performing a first readout operation, according to one or more embodiments. In the following description, description that is substantially the same as the description of FIG. 9 is omitted.

Referring to FIG. 12, in a first readout operation, first data may be read from a normal cell region 111 of a memory cell array 110. Read first data R1_DATA may be provided to an error position information extractor 121.

The error position information extractor 121 may extract first error position information FA1 about a first error bit included in the read first data R1_DATA. For example, the error position information extractor 121 may compare the read first data R1_DATA with reference data stored therein to extract the first error position information FA1. The error position information extractor 121 may provide the first error position information FA1 to a storage region 122.

The storage region 122 may receive the first error position information FA1. An encoder 122_1 may encode the read first data R1_DATA to extract or receive the first error position information FA1. A first memory 122_1 may store the first error position information FA1.

The storage region 122 may store the first error position information FA1. For example, the first memory 122_21 may store the first error position information FA1. The first error position information FA1 may be stored as 7 bits among test bits, which are 8 bits.

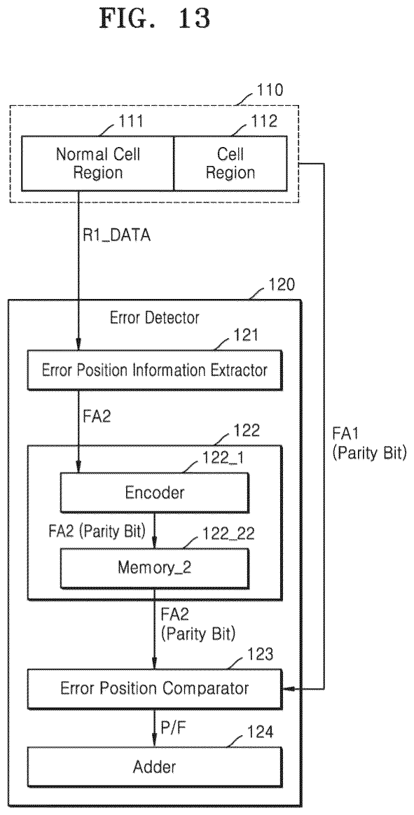

FIG. 13 is a block diagram illustrating an operation of a memory device when performing a second readout operation, according to one or more embodiments.

Referring to FIG. 13, in a second readout operation, first data may be read from a normal cell region 111 of a memory cell array 110. Read first data R1_DATA may be provided to an error position information extractor 121.

The error position information extractor 121 may extract second error position information FA2 about a second error bit included in the read first data R1_DATA. For example, the error position information extractor 121 may compare the read first data R1_DATA with reference data stored therein to extract the second error position information FA2. The error position information extractor 121 may provide the second error position information FA2 to a storage region 122.

The storage region 122 may receive the second error position information FA2. An encoder 122_1 may encode the read first data R1_DATA to extract or receive the second error position information FA2. A second memory 122_22 may store the second error position information FA2. The second error position information FA2 may be stored as 7 bits among test bits, which are 8 bits.

An error position comparator 123 may compare the second error position information FA2, provided from the second memory 122_22, with first error position information FA1 stored in a storage region 122. The error position comparator 123 may compare the first error position information FA1 with the second error position information FA2 to output a signal P/F based on a comparison result. For example, when the first error position information FA1 matches the second error position information FA2, the error position comparator 123 may output a match signal P. For example, when the first error position information FA1 does not match the second error position information FA2, the error position comparator 123 may output a mismatch signal F.

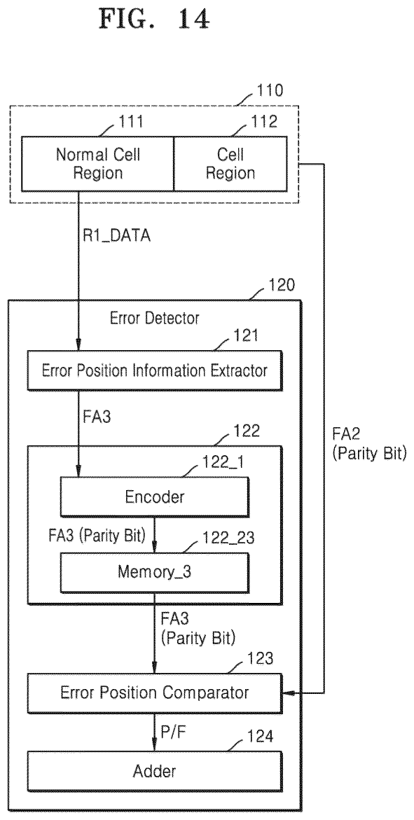

FIG. 14 is a block diagram illustrating an operation of a memory device when performing a third readout operation, according to one or more embodiments.

Referring to FIG. 14, in a third readout operation, first data may be read from a normal cell region 111 of a memory cell array 110. Read first data R1_DATA may be provided to an error position information extractor 121.

The error position information extractor 121 may extract third error position information FA3 about a third error bit included in the read first data R1_DATA. For example, the error position information extractor 121 may compare the read first data R1_DATA with reference data stored therein to extract the third error position information FA3. The error position information extractor 121 may provide the third error position information FA3 to a storage region 122.

The storage region 122 may receive the third error position information FA3. An encoder 122_1 may encode the read first data R1_DATA to extract or receive the third error position information FA3. A third memory 122_23 may store the third error position information FA3. The third error position information FA3 may be stored as 7 bits among test bits, which are 8 bits.

An error position comparator 123 may compare the third error position information FA3, provided from the third memory 122_23, with second error position information FA2 stored in a storage region 122. The error position comparator 123 may compare the second error position information FA2 with the third error position information FA3 to output a signal P/F based on a comparison result. For example, when the second error position information FA2 matches the third error position information FA3, the error position comparator 123 may output a match signal P. For example, when the second error position information FA2 does not match the third error position information FA2, the error position comparator 123 may output a mismatch signal F.

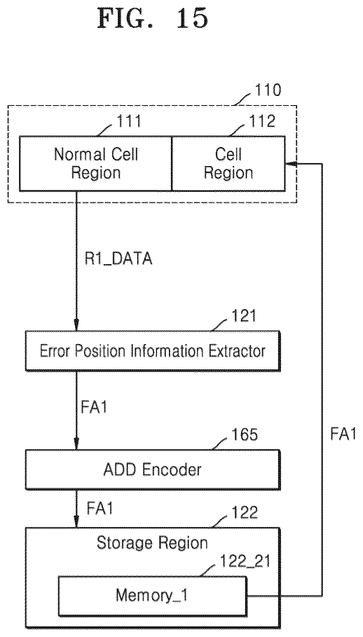

FIG. 15 is a block diagram illustrating an operation of a memory device when performing a first readout operation, according to one or more embodiments. In the following description, description that is substantially the same as the description of FIG. 12 is omitted.

Referring to FIG. 15, unlike FIG. 12, the memory device may be configured with an address encoder 165 instead of the encoder 122_1. The address encoder 165 of FIG. 7 may correspond to the address encoder 165 illustrated in FIG. 2.

In a first readout operation, first data may be read from a normal cell region 111 of a memory cell array 110. Read first data R1_DATA may be provided to an error position information extractor 121.

The error position information extractor 121 may extract first error position information FA1 about a first error bit included in the read first data R1_DATA. For example, the error position information extractor 121 may compare the read first data R1_DATA with reference data stored therein to extract the first error position information FA1. The error position information extractor 121 may provide the first error position information FA1 to a storage region 122.

The address encoder 165 may receive the first error position information FA1. The address encoder 165 may encode the read first data R1_DATA to extract or receive the first error position information FA1. A first memory 122_1 may store the first error position information FA1.

The storage region 122 may store the first error position information FA1. For example, the first memory 122_21 may store the first error position information FA1. The first error position information FA1 may be stored as 7 bits among test bits of 8 bits.

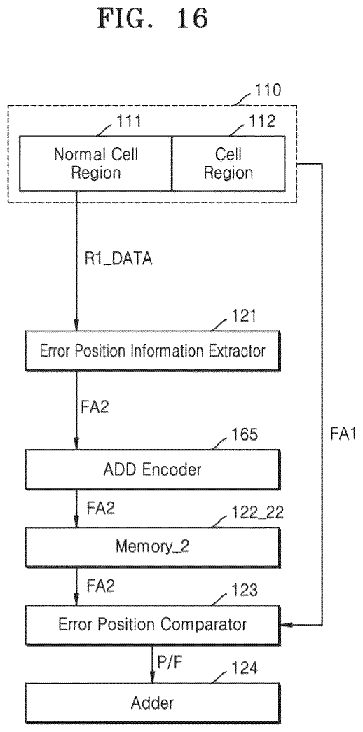

FIG. 16 is a block diagram illustrating an operation of a memory device when performing a second readout operation, according to one or more embodiments. In the following description, description that is substantially the same as the description of FIG. 13 is omitted.

Referring to FIG. 16, unlike FIG. 13, the memory device may be configured with an address encoder 165 instead of the encoder 122_1. The address encoder 165 of FIG. 16 may correspond to the address encoder 165 illustrated in FIG. 2.

In a second readout operation, first data may be read from a normal cell region 111 of a memory cell array 110. Read first data R1_DATA may be provided to an error position information extractor 121.

The error position information extractor 121 may extract second error position information FA2 about a second error bit included in the read first data R1_DATA. For example, the error position information extractor 121 may compare the read first data R1_DATA with reference data stored therein to extract the second error position information FA2. The error position information extractor 121 may provide the second error position information FA2 to a storage region 122.

The address encoder 165 may receive the second error position information FA2. The address encoder 165 may encode the read first data R1_DATA to extract or receive the second error position information FA2. A second memory 122_22 may store the second error position information FA2. The second error position information FA2 may be stored as 7 bits among test bits, which are 8 bits.

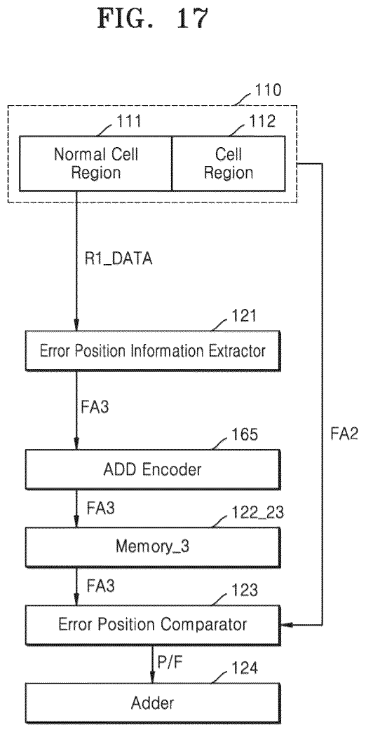

FIG. 17 is a block diagram illustrating an operation of a memory device when performing a third readout operation, according to one or more embodiments. In the following description, description that is substantially the same as the description of FIG. 14 is omitted.

Referring to FIG. 17, unlike FIG. 14, the memory device may be configured with an address encoder 165 instead of the encoder 122_1. The address encoder 165 of FIG. 17 may correspond to the address encoder 165 illustrated in FIG. 2.

In a third readout operation, first data may be read from a normal cell region 111 of a memory cell array 110. Read first data R1_DATA may be provided to an error position information extractor 121.

The error position information extractor 121 may extract third error position information FA3 about a third error bit included in the read first data R1_DATA. For example, the error position information extractor 121 may compare the read first data R1_DATA with reference data stored therein to extract the third error position information FA3. The error position information extractor 121 may provide the third error position information FA3 to a storage region 122.

The address encoder 165 may receive the third error position information FA3. The address encoder 165 may encode the read first data R1_DATA to extract or receive the third error position information FA3. A third memory 122_23 may store the third error position information FA3. The third error position information FA3 may be stored as 7 bits among test bits, which are 8 bits.

An error position comparator 123 may compare the third error position information FA3, provided from the third memory 122_23, with second error position information FA2 stored in a storage region 122. The error position comparator 123 may compare the second error position information FA2 with the third error position information FA3 to output a signal P/F based on a comparison result. For example, when the second error position information FA2 matches the third error position information FA3, the error position comparator 123 may output a match signal P. For example, when the second error position information FA2 does not match the third error position information FA2, the error position comparator 123 may output a mismatch signal F.

Referring to FIGS. 9 and 17, when the adder 124 receives the match signal P, the adder 124 may not perform an addition operation, and when the adder 124 receives the mismatch signal F, the adder 124 may perform the addition operation. For example, when the adder 124 receives the mismatch signal F, the adder 124 may perform a +1 addition operation. For example, in a case where the number of a correctable error bit is 1, when the adder 124 receives the mismatch signal F to perform the +1 addition operation, the accumulated number of error positions is may be 2 and may be greater than 1, and thus, the decision circuit 125 may change the correctable error bit to an uncorrectable error bit to perform processing thereon.

In one or more embodiments, in a case where the number of a CE bit is 1, the error detector 120 may compare whether nth error position information about an nth error bit included in data in an nth readout operation matches n+1th error position information about an n+1th error bit included in the data in an n+1th readout operation, and when a mismatch therebetween is determined, an addition operation may be performed, and moreover, when an addition value is greater than a threshold value which is 2, the error detector 120 may change the number of error bits indicated by addition value to an uncorrectable error bits. Accordingly, in a test process of the memory device, readout may be performed a plurality of times, and thus, faulty cells may be extracted.

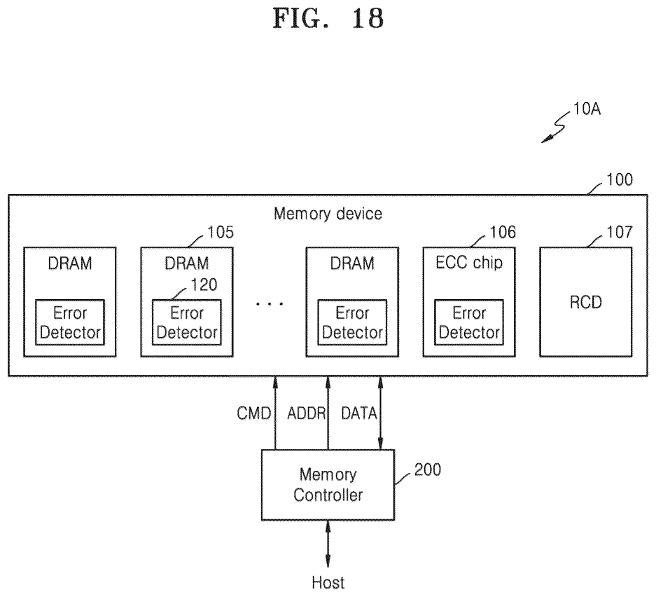

FIG. 18 is a block diagram illustrating a storage system 10A according to one or more embodiments.

Referring to FIG. 18, the storage system 10A may include a memory device 100 and a memory controller 200. The memory controller 200 may control an overall operation of the storage system 10A and may control data exchange between the host and the memory device 100. For example, the memory controller 200 may apply various commands to the memory device 100 to control an operation of the memory device 100. The memory controller 200 may control the memory device 100 to write or read data, based on a request of the host.

The memory controller 200 may transfer or receive an address ADDR, a command CMD, and data DATA (for example, write data or read data) to or from the memory device 100 through a buffer chip 107. The memory controller 200 may further transfer or receive a clock signal CLK and a control signal CTRL to or from the memory device 100 through the buffer chip 107.

According to one or more embodiments, a result where an error of data is corrected may be generated through an on-die ECC operation of the memory device 100.

The memory device 100 may include a plurality of data chips 105, an ECC chip 106, and the buffer chip 107. According to one or more embodiments, each of the plurality of data chips 105 may be DRAM such as DDR SDRAM, LPDDR SDRAM, GDDR SDRAM, LPDDR, or RDRAM, or may be an arbitrary volatile memory device requiring an error correction operation.

The memory device 100 may be implemented as a memory module, and in this case, the memory device 100 may include the plurality of data chips 105, the ECC chip 106, and the buffer chip 107, which are mounted on a printed circuit board, and connectors may be arranged at a certain interval along one edge of a long side of the printed circuit board. When the memory module is inserted into a socket of another device, the connectors may directly contact and be electrically connected to a slot formed in the socket, and the address ADDR, the command CMD, and the data DATA may be transferred to the connectors.

For example, when the memory module has a type such as a registered dual in-line memory module (RDIMM) for servers, the memory module may further include a serial-presence detect (SPD) which stores information about the memory module in a non-volatile form. The SPD may include a volatile memory (for example, electrically erasable programmable read-only memory (EEPROM) and may include various information (for example, the number of row and column addresses, a data width, the number of ranks, a memory density per rank, the number of memory devices, and a memory density per memory device) about a data chip or information about uncorrected read command NECC_CMD.

The plurality of data chips 105 may have a data bus width of 4 bits (X4), 8 bits (X8), 16 bits (X16), or 32 bits (X32). For example, an X8 memory device may transfer or receive data to or from the memory controller 200 through 6 IO pins.

The plurality of data chips 105 may perform a burst operation. A basic unit of the burst operation may be referred to as a burst length BL. The burst length BL may denote the number of data written or read in the burst operation. For example, when the plurality of data chips 105 operate with X8, and the burst length is 16, a length of data input/output through a unit operation of each of the plurality of data chips 105 may be 128 bits (for example, data bus width of 8×burst length of 16=128 bits). In this case, a length of data input/output to/from the memory device 100 through a unit operation may be a value obtained by multiplying 128 bits by the number of data chips 105.

Each of the plurality of data chips 105 may include an error detector 120. The error detector 120 (ECC circuit) may perform an on-die ECC operation on data stored in each of the plurality of data chips 105. In one or more embodiments, the error detector 120 may correct an error of 1 bit included in one unit (for example, one codeword). The ECC chip 106 may also include the error detector 120.

According to one or more embodiments, based on control by the memory controller 200, each of the plurality of data chips 105 may skip the on-die ECC operation, or may ignore a result based on the on-die ECC operation. For example, in a data read operation, each of the plurality of data chips 105 may not correct an error included in data and may immediately output data having an error to the memory controller 200.

When a hard fail occurs in at least one of the plurality of data chips 105, the ECC chip 106 may be used as a spare chip for replacing the ECC chip 106. For example, when a hard fail occurs in an arbitrary data chip, data stored in the arbitrary data chip may be copied to the ECC chip 106. Also, a mapping relationship between the arbitrary data chip and IO pins may be released, and a new mapping relationship between the ECC chip 106 and the IO pins may be formed.

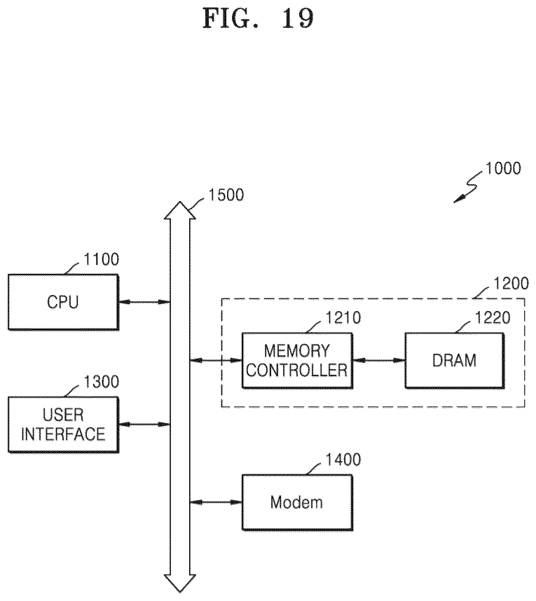

FIG. 19 is a block diagram illustrating a computer system 1000 equipped with DRAM for performing an ECC operation, according to one or more embodiments.

Referring to FIG. 19, the computer system 1000 may be equipped in a mobile device or a desktop computer. The computer system 1000 may include a DRAM memory system 1200, a central processing unit (CPU) 1100, a user interface 1300, and a modem 1400 such as a baseband chipset, which are electrically connected to a system bus 1500. An application chipset, a camera image processor (CIS), and an IO device may be further provided in the computer system 1000.

The user interface 1300 may be an interface which transmits data to a communication network or receives data from the communication network. The user interface 1300 may be an interface which transmits data to a communication network or receives data from the communication network. The user interface 1300 may be a wired/wireless type and may include an antenna or a wired/wireless transceiver. Data provided through the user interface 1300 or the modem 1400 or obtained through processing by the CPU 1100 may be stored in the DRAM memory system 1200.

The DRAM memory system 1200 may include DRAM 1220 and a memory controller 1210. Data obtained through processing by the CPU 1100 or data input from the outside may be stored in the DRAM 1220. The DRAM 1220 may include a memory cell array and an error detector. In a case where an error bit is a correctable error bit capable of being corrected by the error detector, when first error position information about a first error bit included in first data in a first readout operation does not match second error position information about a second error bit included in the first data in a second readout operation, the error detector may perform an addition operation, and when an addition value is greater than a threshold value, which is a correctable error bit, the error detector may change the first error bit or the second error bit to an uncorrectable error bit to perform processing thereon, and a test operation of the DRAM 1220 may end.

When the computer system 1000 is equipment performing wireless communication, the computer system 1000 may be used in a communication system such as code division multiple access (CDMA), global mobile communication system (GSM), North American multiple access (NADC), and CDMA2000. The computer system 1000 may be equipped in information processing devices such as a personal digital assistant (PDA), a portable computer, a web tablet, a digital camera, a portable multimedia player (PMP), a mobile phone, a wireless phone, and a laptop computer.

A cache memory having a high processing speed and a storage such as RAM for storing massive data may be separately provided in a system, but one DRAM system according to one or more embodiments may replace all memories described above. That is, massive data may be quickly stored in a memory device including DRAM, and thus, a structure of a computer system may be simplified.

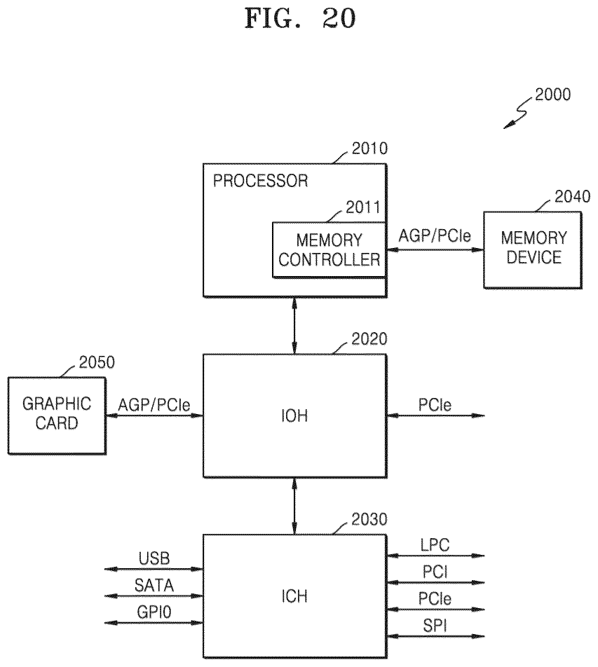

FIG. 20 is a block diagram illustrating an example where a memory device according to one or more embodiments is applied to a computing system 2000.

Referring to FIG. 18, the computing system 2000 may include a processor 2010, an IO hub 2020, an IO controller hub 2030, a memory device 2040, and a graphics card 2050. For example, the computing system 2000 may be an arbitrary computing system such as a personal computer (PC), a server computer, a workstation, a laptop computer, a mobile phone, a smartphone, a PDA, a PMP, a digital camera, a digital television (TV), a set-top box, a music player, a portable game console, and a navigation system.

The processor 2010 may execute various computing functions such as certain calculations or tasks. For example, the processor 2010 may be a microprocessor or a CPU. According to one or more embodiments, the processor 2010 may include one processor core (single core), or may include a plurality of processor cores (multi-core). For example, the processor 2010 may include a dual core, a quad core, and a hexa core. Also, in FIG. 18, the computing system 2000 including one processor 2010 is illustrated, but is not limited thereto and according to embodiments, the computing system 2000 may include a plurality of processors (at least one processor). Also, according to one or more embodiments, the processor 2010 may further include a cache memory disposed in the inside or the outside thereof.

The processor 2010 may include a memory controller 2011 which controls an operation of the memory device 2040. The memory controller 2011 included in the processor 2010 may be referred to as an integrated memory controller (IMC). According to one or more embodiments, the memory controller 2011 may be disposed in the IO hub 2020. The IO hub 2020 including the memory controller 2011 may be referred to as a memory controller hub (MCH).

The processor 2010, the memory controller 2011, and the memory device 2040 may respectively correspond to the host, the memory controller, and the memory device each described above with reference to FIGS. 1 to 19. According to one or more embodiments, the processor 2010 may directly manage an uncorrectable error through an on-die ECC operation.

The memory device 2040 may perform the on-die ECC operation of correcting an error of data stored in a memory cell array. In a case where an error bit is a correctable error bit capable of being corrected by the error detector, when first error position information about a first error bit included in first data in a first readout operation does not match second error position information about a second error bit included in the first data in a second readout operation, the error detector may perform an addition operation, and when an addition value is greater than a threshold value, which is a correctable error bit, and the error detector may change the addition value to an uncorrectable error bit to perform processing thereon. Therefore, in a test process of the memory device 2040, the error detector may perform readout a plurality of times to extract a faulty cell, and thus, a yield rate of memory devices may be enhanced.

The IO hub 2020 may manage data transfer between the processor 2010 and devices such as the graphics card 2050. The IO hub 2020 may be connected to the processor 2010 through various types of interfaces. For example, the IO hub 2020 and the processor 2010 may be connected to each other through interfaces of various standards such as front side bus (FSB), a system bus, a hyper transport, lighting data transport (LDT), quick path interconnect (QPI), a common system interface, and peripheral component interface-express (CSI). In FIG. 18, the computing system 2000 including one IO hub 2020 is illustrated, but is not limited thereto and according to embodiments, the computing system 2000 may include a plurality of IO hubs (at least one IO hub).

The IO hub 2020 may provide various interfaces with devices. For example, the IO hub 2020 may provide accelerated graphics port (AGP) interface, peripheral component interface-express (PCIe) interface, and communications streaming architecture (CSA) interface.

The graphics card 2050 may be connected to the IO hub 2020 through AGP or PCIe. The graphics card 2050 may control a display device for displaying an image. The graphics card 2050 may include an internal processor for image data processing and an internal semiconductor memory device. According to one or more embodiments, the IO hub 2020 may include a graphics device in the IO hub 2020 instead of the graphics card 2050, along with the graphics card 2050 disposed outside the IO hub 2020. A graphics device included in the IO hub 2020 may be referred to as integrated graphics. Also, the IO hub 2020 including a graphics device and a memory controller may be referred to as a graphics and memory controller hub (GMCH).

The IO controller hub 2030 may perform data buffering and interface relay so that various system interfaces operate efficiently. The IO controller hub 2030 may be connected to the IO hub 2020 through an internal bus. For example, the IO hub 2020 and the IO controller hub 2030 may be connected to each other through direct media interface (DMI), hub interface, enterprise southbridge interface (ESI), or PCIe.

The IO controller hub 2030 may provide various interfaces with peripheral devices. For example, the IO controller hub 2030 may provide universal serial bus (USB) port, serial advanced technology attachment (SATA) port, general purpose input/output (GPIO), low pin count (LPC) bus, serial peripheral interface (SPI), PCI, or PCIe. According to one or more embodiments, two or more of the processor 2010, the IO hub 2020, and the IO controller hub 2030 may be implemented as one chipset.

A method of operating a memory device may include: generating a first check bit indicating presence of the first error bit; and generating a second check bit indicating presence of the second error bit.

The method may further include: decoding the first error position information and the second error position information.

The method may further include: comparing the second error position information with the first error position information in the second readout operation; and outputting the signal based on the comparison result.

The method may further include: based on the first error position information matching the second error position information, outputting a match signal as the signal; and based on the first error position information not matching the second error position information, outputting a mismatch signal as the signal.

The method may further include: based on the signal being the match signal, not performing the addition operation; and based on the signal being the mismatch signal, performing the addition operation.

The method may further include: based on the addition value being less than or equal to a threshold value, determining that the error bits are correctable; and based on the addition value being greater than the threshold value, determining that the error bits are uncorrectable.

One or more embodiments herein may constitute an improvement to computer functionality (i.e. improving the functioning of the computer itself) by providing novel memory devices with improved error correction hardware. This improves computational performance by improving error correction and/or identifying faulty memory that would introduce errors during operation (i.e. preventing computational errors), solving a problem in the realm of computer networks.

Hereinabove, exemplary embodiments have been described in the drawings and the specification. Embodiments have been described by using the terms described herein, but this has been merely used for describing the disclosure and has not been used for limiting a meaning or limiting the scope of the disclosure defined in the following claims. Therefore, it may be understood by those of ordinary skill in the art that various modifications and other equivalent embodiments may be implemented from the disclosure. Accordingly, the spirit and scope of the disclosure may be defined based on the spirit and scope of the following claims.

While the disclosure has been particularly shown and described with reference to embodiments thereof, it will be understood that various changes in form and details may be made therein without departing from the spirit and scope of the following claims.

What is claimed is:

1. A memory device comprising:
a memory cell array comprising a normal cell region storing data; and
an error detector configured to detect an error of the data,
wherein the error detector comprises:
an error position information extractor configured to:
in a first readout operation, extract first error position information of a first error bit in first data read from the normal cell region, and
in a second readout operation, extract second error position information of a second error bit in the first data read from the normal cell region; and
an error position comparator configured to:
compare the first error position information with the second error position information, and
output a signal based on a result of the comparison of the first error position information and the second error position information.

2. The memory device of claim 1, further comprising:
a memory,
wherein at least one of the memory cell array or the memory is configured to store at least one of the first error position information and the second error position information.

3. The memory device of claim 1, further comprising:
an encoder configured to:
generate a first check bit indicating presence of the first error bit, and
generate a second check bit indicating presence of the second error bit.

4. The memory device of claim 1, wherein the error position information extractor is further configured to:
compare reference data with the first data read in the first readout operation to generate the first error position information; and
compare the reference data with the first data read in the second readout operation to generate the second error position information.

5. The memory device of claim 1, wherein the error position comparator is further configured to:
based on the first error position information matching the second error position information, output a match signal as the signal; and
based on the first error position information not matching the second error position information, output a mismatch signal as the signal.

6. The memory device of claim 1, wherein the error position comparator is further configured to determine whether to compare the first error position information with the second error position information, based on a first check bit corresponding to the first error position information and a second check bit corresponding to the second error position information,
wherein the first check bit indicates presence of the first error bit, and
wherein the second check bit indicates presence of the second error bit.

7. The memory device of claim 1, further comprising:
an adder configured to perform an addition operation based on the signal output from the error position comparator; and
a decision circuit configured to determine whether error bits including the first error bit and the second error bit are correctable based on an addition value of the adder.

8. The memory device of claim 7, wherein the decision circuit is further configured to:
based on the addition value being less than or equal to a threshold value, determine that the error bits are correctable; and
based on the addition value being greater than the threshold value, determine that the error bits are uncorrectable.

9. The memory device of claim 8, wherein the error position comparator is further configured to compare the second error position information with the first error position information in the second readout operation, and
the adder is further configured to:
based on the signal being a match signal, not perform the addition operation; and
based on the signal being a mismatch signal, perform the addition operation.

10. The memory device of claim 1, wherein the first data comprises 128 or more bits, and
wherein each of the first error position information and the second error position information comprises 8 or less bits.

11. A memory device comprising:
a memory cell array comprising a normal cell region storing data; and
an error detector configured to detect an error of the data, based on the data in a plurality of readout operations,
wherein the error detector comprises:
an error position information extractor configured to:
in a first readout operation among the plurality of readout operations, extract first error position information about a first error bit in first data read from the normal cell region, and
in a second readout operation among the plurality of readout operations, extract second error position information about a second error bit in the first data read from the normal cell region;
an error position comparator configured to:
compare the first error position information with the second error position information, and
output a signal based on a result of the comparison ;
an adder configured to perform an addition operation based on the signal output from the error position comparator; and
a decision circuit configured to determine whether error bits including the first error bit and the second error bit are correctable, based on an addition value of the adder.

12. The memory device of claim 11, further comprising:
an encoder configured to:
generate a first check bit indicating presence of the first error bit, and
generate a second check bit indicating presence of the second error bit.

13. The memory device of claim 12, further comprising:
a decoder configured to decode the first error position information and the second error position information.

14. The memory device of claim 12, wherein the error position comparator is further configured to:
compare the second error position information with the first error position information in the second readout operation; and
output the signal based on the result of the comparison.

15. The memory device of claim 13, wherein the error position comparator is further configured to:
based on the first error position information matching the second error position information, output a match signal as the signal; and
based on the first error position information not matching the second error position information, output a mismatch signal as the signal.

16. The memory device of claim 15, wherein the adder is further configured to:
based on the signal being the match signal, not perform the addition operation; and
based on the signal being the mismatch signal, perform the addition operation.

17. The memory device of claim 11, wherein the decision circuit is further configured to:
based on the addition value being less than or equal to a threshold value, determine that the error bits including the first error bit and the second error bit are correctable; and
based on the addition value being greater than the threshold value, determine that the error bits including the first error bit and the second error bit are uncorrectable.

18. A memory module comprising:
a printed circuit board; and
a plurality of memory chips on the printed circuit board,
wherein each of the plurality of memory chips comprises:
a memory cell array configured to store data and a parity bit; and
an error detector configured to detect an error of the data, based on the data and the parity bit,
wherein the error detector comprises:
an error position information extractor configured to extract nth error position information about an nth error bit in an nth data read from the memory cell array in an nth readout operation and extract an n+1th error position information about an n+1th error bit in an n+1th data read from the memory cell array in an n+1th readout operation, where n is a natural number;
an error position comparator configured to:
compare the nth error position information with the n+1th error position information, and
output a signal based on a result of the comparison of the nth error position information and the n+1th error position information;
an adder configured to perform an addition operation based on the signal output from the error position comparator; and
a decision circuit configured to determine whether error bits including the nth error bit and the n+1th error bit are correctable, based on an addition value of the adder.

19. The memory module of claim 18, wherein the error position comparator is further configured to:
based on the nth error position information matching the n+1th error position information, output a match signal; and
based on the nth error position information not matching the n+1th error position information, output a mismatch signal.

20. The memory module of claim 18, wherein the decision circuit is further configured to:
based on the addition value being less than or equal to a threshold value, determine that the error bits including the nth error bit and the n+1th error bit are correctable; and
based on the addition value being greater than the threshold value, determine that the error bits including the first error bit and the second error bit are uncorrectable.
